(19) United States
(12) Patent Application Publication
(10) Pub. No.: US 2026/0324215 A1
(43) Pub. Date: Oct. 15, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: HYANGYUL KIM, Yongin-si (KR); JAEHONG KIM, Yongin-si (KR); YUNA LEE, Yongin-si (KR); CHANGHAN LEE, Yongin-si (KR); JIWON JUNG, Yongin-si (KR)

(21) Appl. No.: 19/393,671

(22) Filed: Nov. 19, 2025

(30) Foreign Application Priority Data
Apr. 15, 2025 (KR) 10-2025-0048676

(51) Int. Cl. H10K 59/126; H10H 29/855

(52) U.S. Cl. CPC H10K 59/126; H10H 29/855

(57) ABSTRACT

A display device includes a display panel including a first display area having a first resolution and a second display area having a second resolution less than the first resolution, and a light control layer disposed on the display panel that controls a path of light emitted from the display panel. The light control layer includes a plurality of light blocking lines each extending in an extension direction and a light transmitting layer overlapping the plurality of light blocking lines. The plurality of light blocking lines are spaced apart from each other at a constant interval in a direction perpendicular to the extension direction in both the first display area and the second display area. The plurality of light blocking lines include lactam black.

### CROSS-REFERENCE TO RELATED APPLICATION(S)

This application claims priority under 35 U.S.C. § 119 to and benefits from Korean Patent Application No. 10-2025-0048676 filed on Apr. 15, 2025 in the Korean Intellectual Property Office (KIPO), the entire disclosure of which is incorporated by reference.

### TECHNICAL FIELD

Embodiments generally relate to a display device and an electronic device including the same, and more particularly to reducing moiré interference and limiting viewing angles in a display device.

### DISCUSSION OF RELATED ART

A display device is a device for providing visual information to a user. Recently, usage of the display device has diversified as a thickness and a weight of the display device has decreased.

An automobile is one of the most widely used transportations today. Recently, display devices for a vehicle are applied to the automobile to provide various functions to the automobile. The display devices may provide speed information, navigation information, information helpful for driving, or the like to the driver, or may provide entertainment information to a passenger.

At nighttime, an image displayed on the display device disposed in front of the driver or the passenger may also be viewed in a windshield. The image viewed in the windshield may disturb the driver. Further, when the image which the passenger views on the display device is exposed to the driver, the image may disturb the driver.

### SUMMARY

Embodiments provide a display device capable of limiting a viewing angle without substantially reducing a sensing efficiency of a sensor disposed under the display device. Embodiments also provide an electronic device including the display device.

Additional features of the disclosure will be set forth in the description which follows, and in part will be apparent from the description, or may be learned by practice of the disclosure.

A display device according to an embodiment includes a display panel including a first display area having a first resolution and a second display area having a second resolution less than the first resolution, and a light control layer disposed on the display panel that controls a path of light emitted from the display panel. The light control layer includes a plurality of light blocking lines each extending in an extension direction and a light transmitting layer overlapping the plurality of light blocking lines. The plurality of light blocking lines are spaced apart from each other at a constant interval in a direction perpendicular to the extension direction in both the first display area and the second display area. The plurality of light blocking lines include lactam black.

In an embodiment, the plurality of light blocking lines may have an infrared radiation transmittance of at least about 76%.

In an embodiment, the plurality of light blocking lines may have an optical density of at least about 2 with respect to a CIE standard illuminant A at a thickness of 3 micrometers.

In an embodiment, the plurality of light blocking lines may have an optical density of at least about 2 with respect to a CIE standard illuminant C at a thickness of 3 micrometers.

In an embodiment, the light control layer may have an infrared radiation transmittance of at least about 90%.

In an embodiment, the second display area may have an infrared radiation transmittance in a range of about 25% to about 40%.

In an embodiment, a pitch of the plurality of light blocking lines in the first display area may be substantially equal to a pitch of the plurality of light blocking lines in the second display area.

In an embodiment, a pitch of the plurality of light blocking lines may be in a range of about 40 micrometers to about 50 micrometers.

In an embodiment, a width of each of the plurality of light blocking lines in the first display area may be substantially equal to a width of each of the plurality of light blocking lines in the second display area.

In an embodiment, a width of each of the plurality of light blocking lines may be in a range of about 13 micrometers to about 16 micrometers.

In an embodiment, the first display area may include first pixel areas that are repeatedly disposed in a first direction and a second direction perpendicular to the first direction. The second display area may include second pixel areas that are repeatedly disposed in the first direction and the second direction. A size of each of the second pixel areas may be greater than a size of each of the first pixel areas.

In an embodiment, each of the plurality of light blocking lines may extend at an inclination angle inclined with respect to a virtual straight line extending in the first direction.

In an embodiment, the angle at which each of the plurality of light blocking lines may be inclined with respect to the virtual straight line may be in a range of about 5 degrees to about 10 degrees.

In an embodiment, the display device may further include an anti-reflection layer disposed between the display panel and the light control layer.

An electronic device according to an embodiment includes a display device and a processor configured to transmit an image data signal and an input control signal to the display device. The display device includes a display panel including a first display area having a first resolution and a second display area having a second resolution less than the first resolution, and a light control layer disposed on the display panel that controls a path of light emitted from the display panel. The light control layer includes a plurality of light blocking lines each extending in an extension direction and a light transmitting layer overlapping the plurality of light blocking lines. The plurality of light blocking lines are spaced apart from each other at a constant interval in a direction perpendicular to the extension direction in both the first display area and the second display area. The plurality of light blocking lines include lactam black.

In an embodiment, the plurality of light blocking lines may have an infrared radiation transmittance of at least about 76%.

In an embodiment, the plurality of light blocking lines may have an optical density of at least about 2 with respect to a CIE standard illuminant A at a thickness of 3 micrometers.

In an embodiment, the plurality of light blocking lines may have an optical density of at least about 2 with respect to a CIE standard illuminant C at a thickness of 3 micrometers.

In an embodiment, the light control layer may have an infrared radiation transmittance of at least about 90%.

In an embodiment, the second display area may have an infrared radiation transmittance in a range of about 25% to about 40%.

The display device according to embodiments may include the display panel displaying an image and a light control layer disposed on the display panel that limits a viewing angle of the image displayed by the display device. The light control layer may include light blocking lines including a material that blocks visible light but has high infrared radiation transmittance. Accordingly, the light control layer may limit the viewing angle of the image without substantially reducing a sensing efficiency of an infrared sensor disposed under the display device.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure, and together with the description serve to explain the disclosure.

FIG. 1 is a plan view illustrating a display device according to an embodiment;

FIG. 2 is an example cross-sectional view taken along line I-I′ of FIG. 1;

FIG. 3 is an example cross-sectional view illustrating a display panel of FIG. 2;

FIG. 4 is an enlarged plan view of area A of FIG. 1;

FIG. 5 is an enlarged plan view of a portion of a second display area of FIG. 4;

FIG. 6 is a graph illustrating optical densities by wavelength of an embodiment and comparative examples;

FIG. 7 is a graph illustrating light transmittance by wavelength of an embodiment and comparative examples;

FIGS. 8A to 8F are plan views illustrating an example of a method of manufacturing a light control film according to an embodiment; and

FIG. 9 is a block diagram illustrating an electronic device according to an embodiment.

FIG. 10 is an example diagram illustrating an electronic device according to various embodiments.

### DETAILED DESCRIPTION

Various example embodiments will be described more fully hereinafter with reference to the accompanying drawings, in which some example embodiments are shown. The present disclosure may, however, be embodied in many different forms and should not necessarily be construed as limited to the example embodiments set forth herein. Rather, these example embodiments are provided so that this disclosure will be thorough and complete, and will fully convey the scope of the present disclosure to those skilled in the art. In the drawings, the sizes and relative sizes of layers and regions may be exaggerated for clarity.

In the disclosure, various modifications can be made, various forms can be used, and specific embodiments will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

It will be understood that, although the terms first, second, third etc. may be used herein to describe various elements, these elements should not necessarily be limited by these terms. These terms are used to distinguish an element from another. Thus, a first element discussed below could be termed a second element without departing from the teachings of the present disclosure. As used herein, the term “and/or” includes any and all combinations of one or more of the associated listed items.

It will be understood that when an element is referred to as being “connected” or “coupled” to another element, it can be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe an element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. The same reference numerals are used for the same components in the drawings, and redundant descriptions of the same components may be omitted.

While each drawing may represent one or more particular embodiments of the present disclosure, drawn to scale, such that the relative lengths, thicknesses, and angles can be inferred therefrom, it is to be understood that the present disclosure is not necessarily limited to the relative lengths, thicknesses, and angles shown. Changes to these values may be made within the spirit and scope of the present disclosure, for example, to allow for manufacturing limitations and the like.

Embodiments of the disclosure provide a display device and an electronic device including the same that reduces a moiré interference pattern and limit a viewing angle without substantially reducing the ability of an infrared sensor to sense external objects. This is achieved by including light blocking lines on a front side of a display panel and throughout the display area that may include (or be composed of) lactam black (a lactam material having a black appearance). The lines may extend in an extension direction, may be spaced apart from each other at regular intervals, and may form an inclination angle with a horizontal direction of the display device. Such lactam black light blocking lines may be transparent to infrared radiation while limiting visible light transmission so that an infrared sensor disposed under the display device may still adequately sense external objects while overcoming the moiré issues.

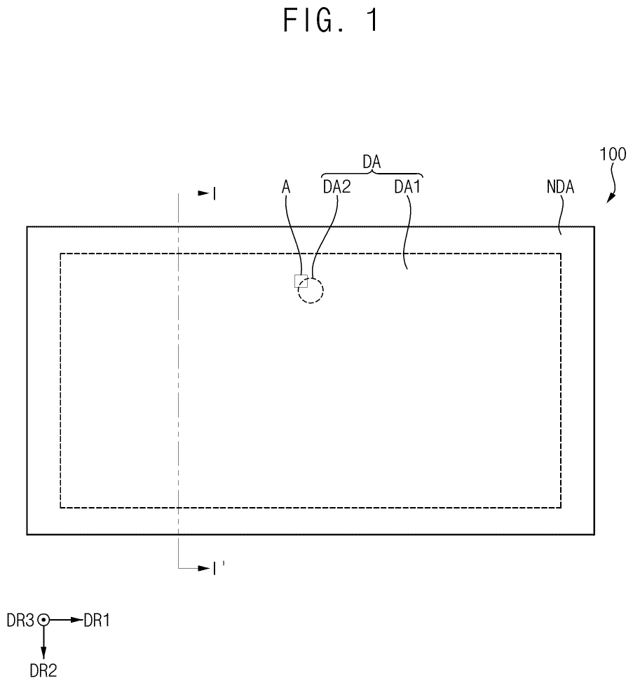

FIG. 1 is a plan view illustrating a display device according to an embodiment.

Referring to FIG. 1, a display device 100 according to an embodiment may include a display surface for displaying an image. In an embodiment, the display surface may be substantially parallel to a plane defined by a first direction DR1 and a second direction DR2 intersecting the first direction DR1. The second direction DR2 may be perpendicular to the first direction DR1. The display device 100 may display the image in a third direction DR3 substantially parallel to a normal direction of the display surface. The third direction DR3 may be perpendicular to each of the first direction DR1 and the second direction DR2. Hereinafter, the third direction DR3 may be referred to as a thickness direction. In an embodiment, the display surface may be a curved surface.

The display device 100 may include a display area DA and a peripheral area NDA. The display area DA may be an area that displays an image by generating light or controlling a transmittance of light provided from an external light source. The peripheral area NDA may be located (or disposed) around the display area DA. For example, the peripheral area NDA may surround at least a portion of the display area DA in a plan view. In an embodiment, the peripheral area NDA may be an area that does not display an image. However, the disclosure is not necessarily limited thereto, and an image may be displayed in at least a portion of the peripheral area NDA.

Multiple pixels may be disposed in the display area DA. In an embodiment, each of the pixels may emit one of red light, green light, and blue light. For example, pixels, which are adjacent to each other and emitting red light, green light, and blue light, respectively, may form a pixel (e.g., single pixel). Multiple pixels may be repeatedly disposed in the display area DA.

Each of the pixels may include a pixel circuit and a light emitting element electrically connected to the pixel circuit. The pixel circuit may include at least one thin film transistor and at least one capacitor. The light emitting element may emit light based on a driving current provided from the pixel circuit. The light emitting element may include an organic light emitting diode, an inorganic light emitting diode, a quantum dot light emitting diode, a micro light emitting diode, or the like.

In an embodiment, the display area DA may include a first display area DA1 and a second display area DA2. For example, the first display area DA1 may surround the second display area DA2 in a plan view. FIG. 1 illustrates that the second display area DA2 has a circular planar shape, but this is an example and the disclosure is not necessarily limited thereto, and the second display area DA2 may have various planar shapes, such as a square, an oval, or the like.

The second display area DA2 may be an area having higher light transmittance than the first display area DA1. For example, the second display area DA2 may be an area having higher infrared radiation transmittance than the first display area DA1. For example, an infrared sensor may be disposed under the second display area DA2 of the display device 100 (e.g., disposed in a direction opposite to the third direction DR3 from the second display area DA2 of the display device 100). The infrared sensor may sense an external object by receiving infrared radiation which is reflected from the object external to the display device 100 (e.g., located in the third direction DR3 from the display device 100) and is transmitted through the second display area DA2 of the display device 100. In the disclosure, infrared radiation transmittance may mean transmittance for light having a wavelength of at least 750 nanometers.

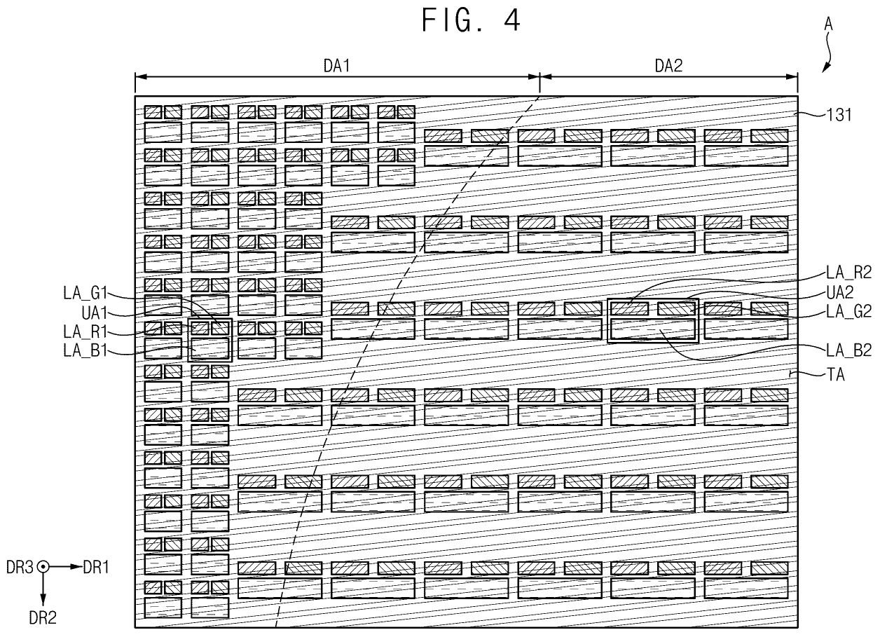

A resolution of the second display area DA2 may be less than a resolution of the first display area DA1. The number of the pixels disposed in the same-sized area may be less in the second display area DA2 than in the first display area DA1. This may be because, as illustrated in FIG. 4, the second display area DA2 includes a transmitting area TA to improve infrared radiation transmittance.

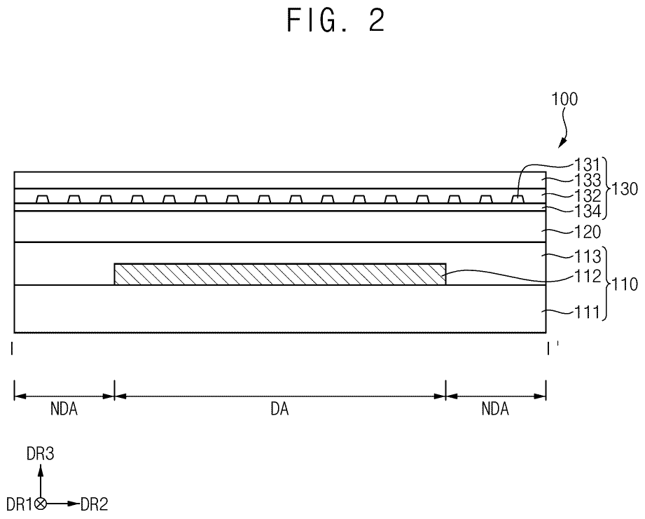

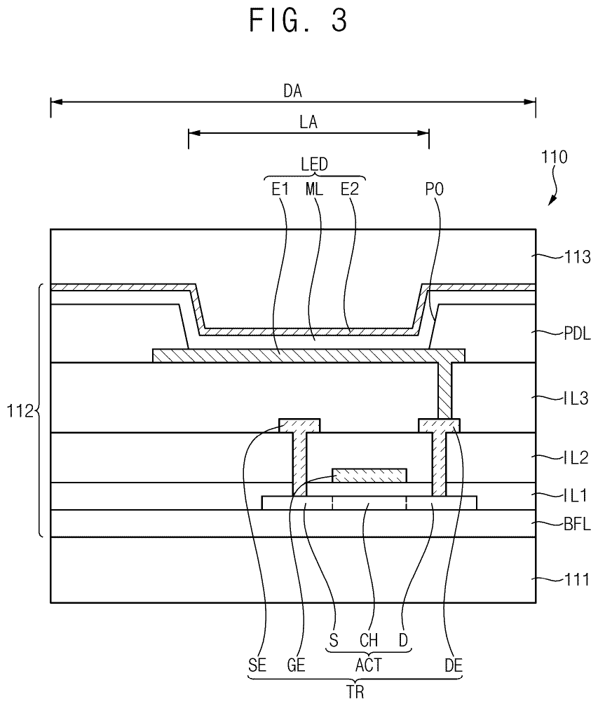

FIG. 2 is an example cross-sectional view taken along line I-I′ of FIG. 1. FIG. 3 is an example cross-sectional view illustrating a display panel of FIG. 2.

Referring to FIGS. 1 to 3, in an embodiment, the display device 100 may include a display panel 110, an anti-reflection layer 120, and a light control layer 130.

The display panel 110 may include a substrate 111, a display layer 112, and an encapsulation layer 113. The display panel 110 may include the display area DA and the peripheral area NDA.

The substrate 111 may form a base for the display panel 110. The substrate 111 may be an insulating substrate including or formed of a transparent or a non-transparent material. The substrate 111 may be flexible or rigid. The substrate 111 may have a single layer structure or a multi-layer structure in which multiple layers including different materials are disposed in a stacking configuration.

The display layer 112 may be disposed in the display area DA on the substrate 111. In an embodiment, the display layer 112 may include a buffer layer BFL, a transistor TR, first to third insulating layers IL1, IL2, and IL3, a light emitting element LED, and a pixel defining layer PDL.

The buffer layer BFL may be disposed on the substrate 111. The buffer layer BFL may prevent or reduce impurities, such as oxygen or moisture, from penetrating into an upper portion of the display layer 112 through the substrate 111. The buffer layer BFL may include an inorganic material, such as a silicon compound, a metal oxide, or the like. For example, the buffer layer BFL may include silicon oxide (SiOₓ), silicon nitride (SiNₓ), silicon oxynitride (SiOₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), or other compounds. These may be used alone or in combination with each other. The buffer layer BFL may have a single layer structure or a multi-layer structure including multiple insulating layers.

The transistor TR may be disposed on the buffer layer BFL. The transistor TR may include an active layer ACT, a gate electrode GE, a first contact electrode SE, and a second contact electrode DE.

The active layer ACT may be disposed on the buffer layer BFL. The active layer ACT may include an oxide semiconductor, a silicon semiconductor, an organic semiconductor, or the like. For example, the oxide semiconductor may include at least one selected from oxides of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include an amorphous silicon, a polycrystalline silicon, or the like. The active layer ACT may include a first contact area S, a second contact area D, and a channel area CH located between the first contact area S and the second contact area D. Each of the first contact area S and the second contact area D may have higher conductivity than a conductivity of the channel area CH.

The first insulating layer IL1 may be disposed on the active layer ACT. The first insulating layer IL1 may overlap (or cover) the active layer ACT on the buffer layer BFL. The first insulating layer IL1 may include an inorganic insulating material.

The gate electrode GE may be disposed on the first insulating layer IL1. The gate electrode GE may overlap the channel area CH of the active layer ACT. The gate electrode GE may include a conductive material, such as a metal, an alloy, a conductive metal nitride, a conductive metal oxide, a transparent conductive material, or the like. For example, the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlNₓ), tungsten nitride (WNₓ), titanium nitride (TiNₓ), chromium nitride (CrNₓ), tantalum nitride (TaNₓ), strontium ruthenium oxide (SrRuOₓ), zinc oxide (ZnOₓ), indium tin oxide (ITO), tin oxide (SnOₓ), indium oxide (InOₓ), gallium oxide (GaOₓ), indium zinc oxide (IZO), or the like. These may be used alone or in combination with each other. The gate electrode GE may have a single layer structure or a multi-layer structure including multiple conductive layers.

The second insulating layer IL2 may be disposed on the gate electrode GE. The second insulating layer IL2 may overlap (or cover) the gate electrode GE on the first insulating layer IL1. The second insulating layer IL2 may include an inorganic insulating material.

The first contact electrode SE and the second contact electrode DE may be disposed on the second insulating layer IL2. The first contact electrode SE and the second contact electrode DE may be connected to the first contact area S and the second contact area D of the active layer ACT, respectively. Each of the first contact electrode SE and the second contact electrode DE may include a conductive material.

The third insulating layer IL3 may be disposed on the first contact electrode SE and the second contact electrode DE. The third insulating layer IL3 may include an organic insulating material. For example, the third insulating layer IL3 may include a photoresist, a polyacryl-based resin, a polyimide-based resin, a polyamide-based resin, a siloxane-based resin, an acrylic resin, an epoxy-based resin, or the like. These may be used alone or in combination with each other.

The light emitting element LED may be disposed on the third insulating layer IL3. The light emitting element LED may include a first electrode E1, an intermediate layer ML, and a second electrode E2.

The first electrode E1 may be disposed on the third insulating layer IL3. The first electrode E1 may include a conductive material. The first electrode E1 may be connected to the second contact electrode DE through a contact hole formed in the third insulating layer IL3. Accordingly, the first electrode E1 may be electrically connected to the transistor TR. For example, the first electrode E1 may be an anode of the light emitting element LED.\The pixel defining layer PDL may be disposed on the first electrode E1. The pixel defining layer PDL may overlap (or cover) a peripheral portion of the first electrode E1 and may define a pixel opening PO that exposes a central portion of the first electrode E1. A light emitting area LA, which is an area where light is emitted from the light emitting element LED, may be defined by the pixel opening PO. The pixel defining layer PDL may include an organic insulating material. In an embodiment, the pixel defining layer PDL may further include an inorganic material or an organic material including (or containing) a light blocking material having a black color.

The intermediate layer ML may be disposed on the first electrode E1 and the pixel defining layer PDL. In an embodiment, the intermediate layer ML may include a lower functional layer, an emission layer disposed on the lower functional layer, and an upper functional layer disposed on the emission layer. The lower functional layer may include a hole injection layer and/or a hole transport layer. The upper functional layer may include an electron transport layer and/or an electron injection layer.

The second electrode E2 may be disposed on the intermediate layer ML. The second electrode E2 may include a conductive material. For example, the second electrode E2 may be a cathode of the light emitting element LED.

The encapsulation layer 113 may be disposed on the second electrode E2. The encapsulation layer 113 may include at least one inorganic encapsulation layer and at least one organic encapsulation layer. In an embodiment, the encapsulation layer 113 may include an encapsulation substrate spaced apart from the second electrode E2, and the encapsulation substrate may be bonded to the substrate 111 by a sealant in the peripheral area NDA.

The anti-reflection layer 120 may be disposed on the display panel 110. The anti-reflection layer 120 may reduce a reflectivity of external light incident from an exterior of the display device 100. In an embodiment, the anti-reflection layer 120 may include a retarder and/or a polarizer. In an embodiment, the anti-reflection layer 120 may include a light blocking layer and color filters. In an embodiment, the anti-reflection layer 120 may include a destructive interference structure.

The light control layer 130 may be disposed on the anti-reflection layer 120. The light control layer 130 may control a path of light emitted from the display panel 110. For example, the light control layer 130 may limit a viewing angle of the image displayed by the display device 100.

In an embodiment, the light control layer 130 may include multiple light blocking lines 131, a light transmitting layer 132, and a base layer 133.

Each of the light blocking lines 131 may extend in one (e.g., a single) direction referred to as the extension direction or DR4. The light blocking lines 131 may be spaced apart from each other at a constant interval in a direction perpendicular to the extension direction. The light blocking lines 131 may be disposed in both the first display area DA1 and the second display area DA2.

In an embodiment, the light blocking lines 131 may include a material that blocks visible light but has high infrared radiation transmittance. For example, the light blocking lines 131 may include an organic black material. For example, the light blocking lines 131 may include lactam black (a lactam material having a black appearance, as noted earlier). Lactam Black may include a material such as former U.S. Trademark “Irgaphor” Black S 0100 CF by BASF or the like as, for example disclosed to have a formula in paragraph of US 2025/0115763 and in JP 2022/065931A, EP 4089150A1, and WO2015/046178. Accordingly, the light blocking lines 131 may block visible light which is emitted from the display panel 110 to an exterior of the display device 100 (e.g., in the third direction DR3), but may transmit most infrared radiation which is reflected from the object located external to the display device 100 (e.g., in the third direction DR3) and is incident on the display device 100, without substantial blocking. Therefore, the light control layer 130 may limit the viewing angle of the image displayed by the display device 100 without substantially reducing a sensing efficiency of the infrared sensor.

The light transmitting layer 132 may overlap (or cover) the light blocking lines 131. In an embodiment, the light transmitting layer 132 may define grooves corresponding to the light blocking lines 131, respectively. The light blocking lines 131 may fill the grooves of the light transmitting layer 132, respectively. For example, the light transmitting layer 132 may include a transparent resin.

The base layer 133 may be disposed on the light transmitting layer 132. The base layer 133 may include a transparent resin. In an embodiment, the base layer 133 may be omitted.

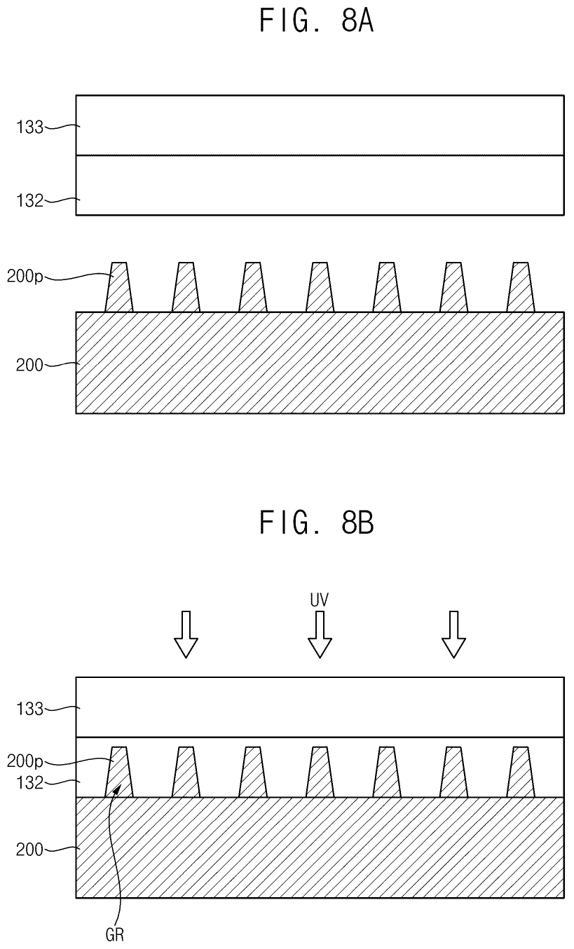

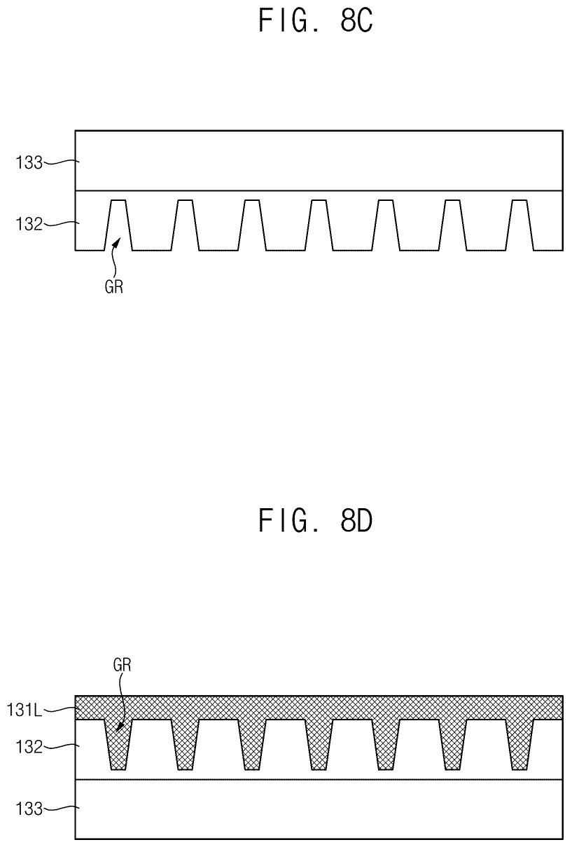

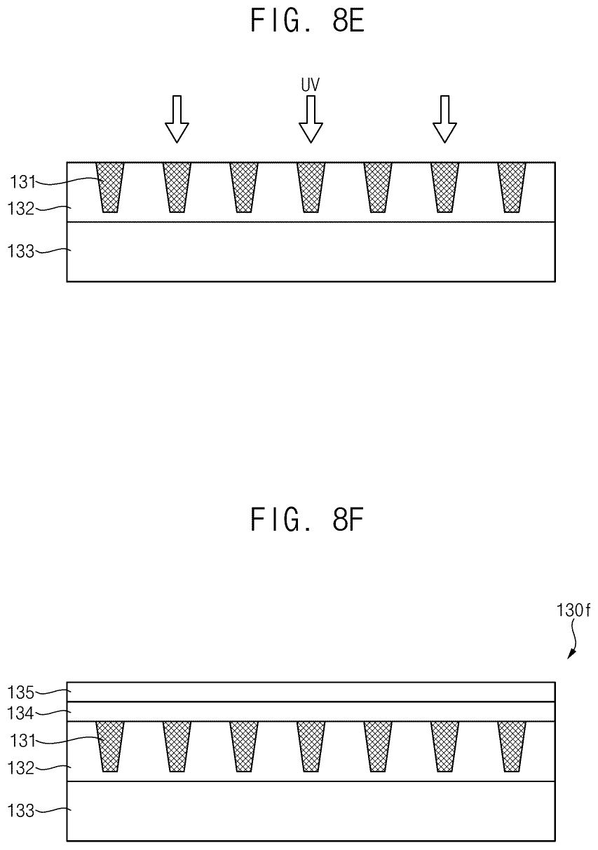

In an embodiment, the light control layer 130 may further include an adhesive layer 134. For example, the light control layer 130 may be manufactured in the form of a separate attachable film (see FIGS. 8A to 8F), and may be attached onto the anti-reflection layer 120. The adhesive layer 134 may attach the light blocking lines 131 and the light transmitting layer 132 to the anti-reflection layer 120.

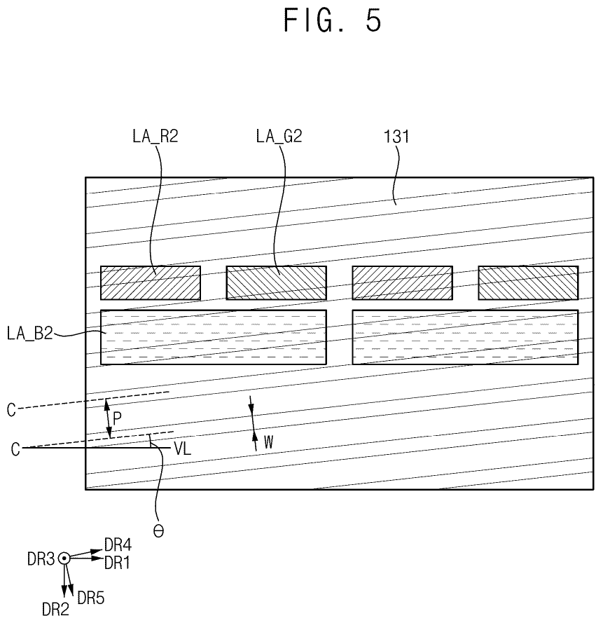

FIG. 4 is an enlarged plan view of area A of FIG. 1. FIG. 5 is an enlarged plan view of a portion of a second display area of FIG. 4.

To the extent that some components of display device 100 are not described in detail with respect to FIGS. 4-5, it may be understood that the element is at least similar to a corresponding element that has been described elsewhere within the present disclosure. Hereinafter, arrangements of the light emitting areas and the light blocking lines 131 near a boundary between the first display area DA1 and the second display area DA2 of the display device 100 will be described in more detail with reference to FIGS. 4 and 5.

Referring to FIGS. 1, 4 and 5, the first display area DA1 may include first-first light emitting areas LA_R1, first-second light emitting areas LA_G1 and first-third light emitting areas LA_B1. Light emitting elements (e.g., the light emitting element LED of FIG. 3) may be disposed in the first-first light emitting areas LA_R1, the first-second light emitting areas LA_G1, and the first-third light emitting areas LA_B1, respectively. For example, the first-first light emitting areas LA_R1 may emit red light, the first-second light emitting areas LA_G1 may emit green light, and the first-third light emitting areas LA_B1 may emit blue light, but the disclosure is not necessarily limited thereto. A first-first light emitting area LA_R1, a first-second light emitting area LA_G1, and a first-third light emitting area LA_B1 adjacent to each other may form a first pixel area UA1. One (e.g., a single) pixel may be disposed in each of the first pixel areas UA1.

In an embodiment and in the first display area DA1, the first pixel areas UA1 may be repeatedly disposed in the first direction DR1 and the second direction DR2. For example, in the first display area DA1, the first pixel areas UA1 may be disposed in a matrix form along rows extending in the first direction DR1 and columns extending in the second direction DR2.

The second display area DA2 may include second-first light emitting areas LA_R2, second-second light emitting areas LA_G2, and second-third light emitting areas LA_B2. Light emitting elements (e.g., the light emitting element LED of FIG. 3) may be disposed in the second-first light emitting areas LA_R2, the second-second light emitting areas LA_G2, and the second-third light emitting areas LA_B2. For example, the second-first light emitting areas LA_R2 may emit red light, the second-second light emitting areas LA_G2 may emit green light, and the second-third light emitting areas LA_B2 may emit blue light, but the disclosure is not necessarily limited thereto. A second-first light emitting area LA_R2, a second-second light emitting area LA_G2, and a second-third light emitting area LA_B2 adjacent to each other may form a second pixel area UA2. One (e.g., a single) pixel may be disposed in each of the second pixel areas UA2.

In an embodiment and in the second display area DA2, the second pixel areas UA2 may be repeatedly disposed in the first direction DR1 and the second direction DR2. For example, in the second display area DA2, the second pixel areas UA2 may be disposed in a matrix form along rows extending in the first direction DR1 and columns extending in the second direction DR2.

The second display area DA2 may further include the transmitting area TA around the second-first light emitting areas LA_R2, the second-second light emitting areas LA_G2, and the second-third light emitting areas LA_B2. No light emitting elements may be disposed in the transmitting area TA. The transmitting area TA may not emit light, but may transmit light incident from the exterior. Since the second display area DA2 includes the transmitting area TA, the light transmittance of the second display area DA2 may be higher than the light transmittance of the first display area DA1. The infrared radiation transmittance of the second display area DA2 may be higher than the infrared radiation transmittance of the first display area DA1.

A first resolution of the first display area DA1 may be greater than the second resolution of the second display area DA2. In the same-sized area, more first pixel areas UA1 may be disposed than second pixel areas UA2. For example, the number of the pixels disposed in the same-sized area may be less in the second display area DA2 than in the first display area DA1. In an embodiment, a size of each of the second pixel areas UA2 may be greater than a size of each of the first pixel areas UA1. A size of each of the second-first light emitting areas LA_R2 may be greater than a size of each of the first-first light emitting areas LA_R1, a size of each of the second-second light emitting areas LA_G2 may be greater than a size of each of the first-second light emitting areas LA_G1, and a size of each of the second-third light emitting areas LA_B2 may be greater than a size of each of the first-third light emitting areas LA_B1. However, this is an example and the disclosure is not necessarily limited thereto, and the size of each of the second pixel areas UA2 may be substantially equal to the size of each of the first pixel areas UA1.

The light blocking lines 131 may be disposed in both the first display area DA1 and the second display area DA2. The shape and arrangement of the light blocking lines 131 may be the same in the first display area DA and the second display area DA2. Each of the light blocking lines 131 may extend in one (e.g., single direction) called the extension direction (or DR4). The light blocking lines 131 may be spaced apart from each other at a constant interval in a direction perpendicular to the extension direction.

FIGS. 4 and 5 illustrate that each of the light blocking lines 131 extends in a fourth direction DR4, which is a diagonal direction inclined at a certain acute inclination angle θ from the first direction DR1 in a plan view, but the disclosure is not necessarily limited thereto, and each of the light blocking lines 131 may extend in the first direction DR1.

In an embodiment, as illustrated in FIGS. 4 and 5, each of the light blocking lines 131 may extend in the fourth direction DR4. Each of the light blocking lines 131 may extend at a certain inclination angle θ from a virtual straight line VL which extends in the first direction DR1. In an embodiment, each of the light blocking lines 131 may extend in a straight line throughout the entire display area DA. Hereinafter, the fourth direction DR4 may be referred to as an extension direction, and the inclination angle θ at which the extension direction DR4 is inclined from the virtual straight line VL may be referred to as an inclination angle.

In an embodiment, each of the light blocking lines 131 may have a constant width W in a fifth direction DR5 perpendicular to the fourth direction DR4. The fourth direction DR4 may be referred to as the extension direction, and the fifth direction DR5 may be referred to as a width direction. In an embodiment, the width W of each of the light blocking lines 131 may be constant throughout the entire display area DA. The width W of each of the light blocking lines 131 in the first display area DA1 may be substantially equal to the width W of each of the light blocking lines 131 in the second display area DA2.

In an embodiment, the light blocking lines 131 may be spaced apart from each other at a constant interval in the width direction DR5. A central axis C of each of the light blocking lines 131 may be defined as an virtual straight line, which extends in the extension direction DR4 and passes through a center of each of the light blocking lines 131 in the width direction DR5. A pitch P of the light blocking lines 131 may be defined as a distance between the central axes C of two adjacent light blocking lines 131 in the width direction DR5. In an embodiment, the pitch P of the light blocking lines 131 may be constant throughout the entire display area DA. The pitch P of the light blocking lines 131 in the first display area DA1 may be substantially equal to the pitch P of the light blocking lines 131 in the second display area DA2.

The shape and arrangement of the light blocking lines 131 may be designed to prevent or reduce moiré issues from occurring in the display device 100 in both the first display area DA1 and the second display area DA2. The light blocking lines 131 may have the pitch P, the width W, and the inclination angle θ that are optimized to prevent or reduce moiré issues from occurring in the display device 100 in both the first display area DA1 and the second display area DA2 by considering both the shape and arrangement of the light emitting areas LA_R1, LA_G1, and LA_B1 of the first display area DA1 and the shape and arrangement of the light emitting areas LA_R2, LA_G2, and LA_B2 of the second display area DA2. In an embodiment, a first numerical range of the pitch P, the width W, and the inclination angle θ that can prevent or reduce moiré issues may be calculated based on the shape and arrangement of the light emitting areas LA_R1, LA_G1, and LA_B1 of the first display area DA1, a second numerical range of the pitch P, the width W, and the inclination angle θ that can prevent or reduce moiré issues may be calculated based on the shape and arrangement of the light emitting areas LA_R2, LA_G2, and LA_B2 of the second display area DA2, and then, the pitch P, the width W, and the inclination angle θ of the light blocking lines 131 may be determined in a third numerical range, defined as the intersection of the first numerical range and the second numerical range.

In an embodiment and throughout the entire display area, the pitch P of the light blocking lines 131 may be in a range of about 40 micrometers to about 50 micrometers. In an embodiment and throughout the entire display area DA, the width W of each of the light blocking lines 131 may be in a range of about 13 micrometers to about 16 micrometers. In an embodiment and throughout the entire display area DA, the inclination angle θ of each of the light blocking lines 131 may be in a range of about 5 degrees to about 10 degrees. However, this is an example and the disclosure is not necessarily limited thereto, and the pitch P, width W, and inclination angle θ of the light blocking lines 131 may be variously changed depending on the shape and arrangement of the light emitting areas LA_R1, LA_G1, and LA_B1 in the first display area DA1 and the shape and arrangement of the light emitting areas LA_R2, LA_G2, and LA_B2 in the second display area DA2.

As described above, the light blocking lines 131 may include a material that blocks visible light but has high infrared radiation transmittance. In an embodiment, the light blocking lines 131 may have an optical density of at least about 2 with respect to a CIE standard illuminant A at a thickness of 3 micrometers. In an embodiment, the light blocking lines 131 may have an optical density of at least about 2 with respect to a CIE standard illuminant C at a thickness of 3 micrometers.

In an embodiment, the light blocking lines 131 may have an infrared radiation transmittance of at least about 76%. In an embodiment, the light control layer 130 including the light blocking lines 131 may have an infrared radiation transmittance of at least about 90%. Preferably, the light control layer 130 may have an infrared radiation transmittance of at least about 94%. The infrared radiation transmittance of the light control layer 130 may be set according to the infrared radiation transmittance of the light blocking lines 131, the pitch P and the width W of the light blocking lines 131.

In an embodiment and in the display panel 110 to which the light control layer 130 is not attached, the second display area DA2 may have an infrared radiation transmittance in a range of about 28% to about 40%. If the display panel 110 is formed such that the infrared radiation transmittance of the second display area DA2 is at least about 40%, the second resolution of the second display area DA2 may become excessively low. In an embodiment and in the display device 100 to which the light control layer 130 is attached on the display panel 110, the second display area DA2 may have an infrared radiation transmittance in a range of about 25% to about 40%.

According to embodiments, the light blocking lines 131 may block visible light which is emitted from the display panel 110 to an exterior of the display device 100 (e.g., in the third direction DR3), but may transmit most incident infrared radiation which is reflected from the object located external to the display device 100 (e.g., in the third direction DR3) and is incident on the display device 100, without substantial blocking. Therefore, the light control layer 130 may limit the viewing angle of the image displayed by the display device 100 without substantially reducing a sensing efficiency of the infrared sensor.

Hereinafter, effects of the disclosure will be described in more detail through specific experimental examples.

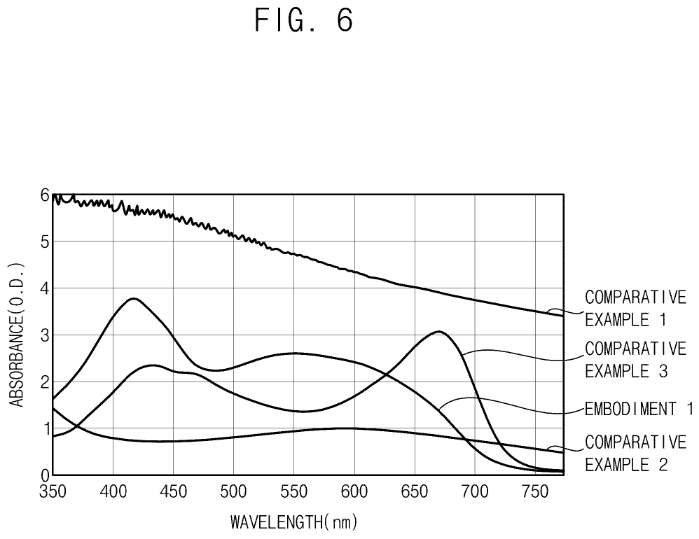

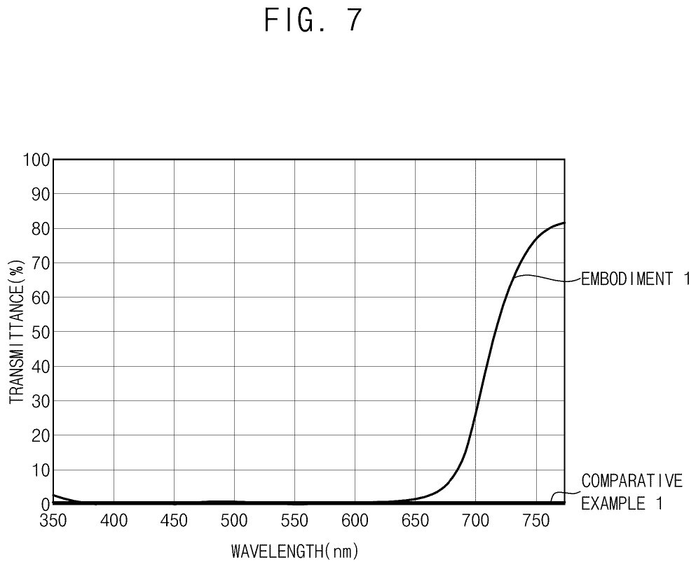

FIG. 6 is a graph illustrating optical densities by wavelength of Embodiment 1 and Comparative Examples. FIG. 7 is a graph illustrating light transmittance by wavelength of Embodiment 1 and a Comparative Example.

FIG. 6 is a graph illustrating the results of measuring optical density by wavelength for light blocking lines having a thickness of 3 micrometers and including 25 wt % of various types of black pigments dispersed in 75 wt % of an acrylate resin. In FIG. 6, Embodiment 1 used lactam black (S 0100 CF, formerly “Irgaphor” Black S 0100CF by BASF) as the black pigment having a formula as mentioned in paragraph of US 2025/0115763 and in JP 2022/065931A, EP 4089150A1, WO2015/046178, Comparative Example 1 used carbon black (PBk7 of Color Index International) as the black pigment, Comparative Example 2 used Paliotol® Black (L 0080) by Sun Chemical as the black pigment, and Comparative Example 3 used Paliogen® Black (L 0086) by Sun Chemical as the black pigment.

TABLE 1

Optical density (O.D.)

| | CIE standard | CIE standard |
|---|---|---|
| Type | illuminant A | illuminant C |
| Embodiment 1 | 2.27 | 2.37 |
| Comparative Example 1 | 0.97 | 0.91 |
| Comparative Example 2 | 1.36 | 1.53 |
| Comparative Example 3 | 4.43 | 4.20 |

Table 1 shows the results of measuring optical density of Embodiment 1, Comparative Example 1, Comparative Example 2, and Comparative Example 3 with respect to the CIE standard illuminant A and the CIE standard illuminant C. In Table 1, the optical density with respect to the CIE standard illuminant A may represent an average value of optical density in the wavelength range of the CIE standard illuminant A, and the optical density with respect to the CIE standard illuminant C may represent an average value of optical density in the wavelength range of the CIE standard illuminant C.

FIG. 7 is a graph illustrating the results of measuring light transmittance by wavelength of Embodiment 1 and Comparative Example 1.

Referring to FIG. 6, Table 1, and FIG. 7, it can be seen that the optical density of Embodiment 1 in visible wavelength range is at least 2, which is less than that of Comparative Example 1, but greater than that of Comparative Example 2 and Comparative Example 3. For example, the optical density of Embodiment 1 was measured to be 2.27 with respect to the CIE standard illuminant A, and 2.37 with respect to the CIE standard illuminant C. It can be seen that Comparative Example 1 has the highest optical density of 4 or more in visible wavelength range, but has very low transmittance in infrared radiation wavelength range (wavelengths of at least 750 nm). For example, transmittance of Embodiment 1 was measured to be 76% at a wavelength of 750 nm. Therefore, it can be noted that the most suitable black pigment for the light blocking lines 131 of the disclosure, which are configured to block visible light but transmit most incident infrared radiation without substantial blocking is the lactam black of Embodiment 1. Therefore, embodiments of the disclosure provide a display device and an electronic device including the same that reduces a moiré interference pattern and limits a viewing angle without substantially reducing the ability of an infrared sensor to sense external objects. This is achieved by including light blocking lines on a front side of a display panel and throughout the display area that may include (or be composed of) lactam black (a lactam based material having a black appearance). The lines may extend in an extension direction and may be spaced apart from each other at regular intervals, and may form an inclination angle with a horizontal direction of the display device. Such lactam black light blocking lines are transparent to infrared radiation while limiting visible light transmission so that an infrared sensor under the display device can still adequately sense external objects.

FIGS. 8A to 8F are plan views illustrating an example of a method of manufacturing a light control film according to an embodiment.

Hereinafter, an example of a method of manufacturing a light control film 130f corresponding to the light control layer 130 of FIG. 2 will be described with reference to FIGS. 8A to 8F.

As illustrated in FIGS. 8A to 8C, the light transmitting layer 132 may be formed on a surface of the base layer 133. Grooves GR may be formed in the light transmitting layer 132 by an imprinting process using a mold 200. The mold 200 may include multiple protrusions 200p, which extend in a direction and are spaced apart from each other in a direction perpendicular to the a direction. The mold 200 may be disposed such that the protrusions 200p face a surface of the light transmitting layer 132 opposite to the base layer 133, the mold 200 may be pressed, and UV light may be irradiated. Thereafter, the mold 200 may be removed from the light transmitting layer 132 to form the grooves GR, which are recessed from the a surface of the light transmitting layer 132 toward the base layer 133. In an embodiment, the base layer 133 may be omitted.

As illustrated in FIG. 8D, a resin including an organic black material dispersed therein may be applied to fill the grooves GR of the light transmitting layer 132 to form a resin layer 131L. Thereafter, a portion of the resin layer 131L (e.g., an upper portion of FIG. 8D) may be removed by a scrubbing process to expose the a surface of the light transmitting layer 132, and UV light may be irradiated. Accordingly, the light blocking lines 131, which are respectively fill in the grooves GR of the light transmitting layer 132, may be formed.

As illustrated in FIG. 8F, the adhesive layer 134 may be attached to the a surface of the light transmitting layer 132 and surfaces of the light blocking lines 131. Then, a release film 135 may be attached to a surface of the adhesive layer 134, thereby manufacturing the light control film 130f.

In a manufacturing process of the display device 100 of FIG. 2, the release film 135 may be removed from the light control film 130f cut to a required size, and the adhesive layer 134 may be attached to the anti-reflection layer 120 of FIG. 2, thereby forming the light control layer 130 of FIG. 2.

The display device according to embodiments may be applied to various electronic devices.

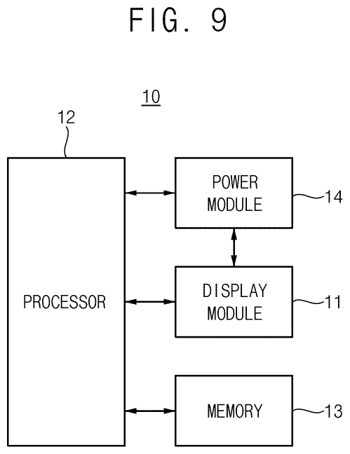

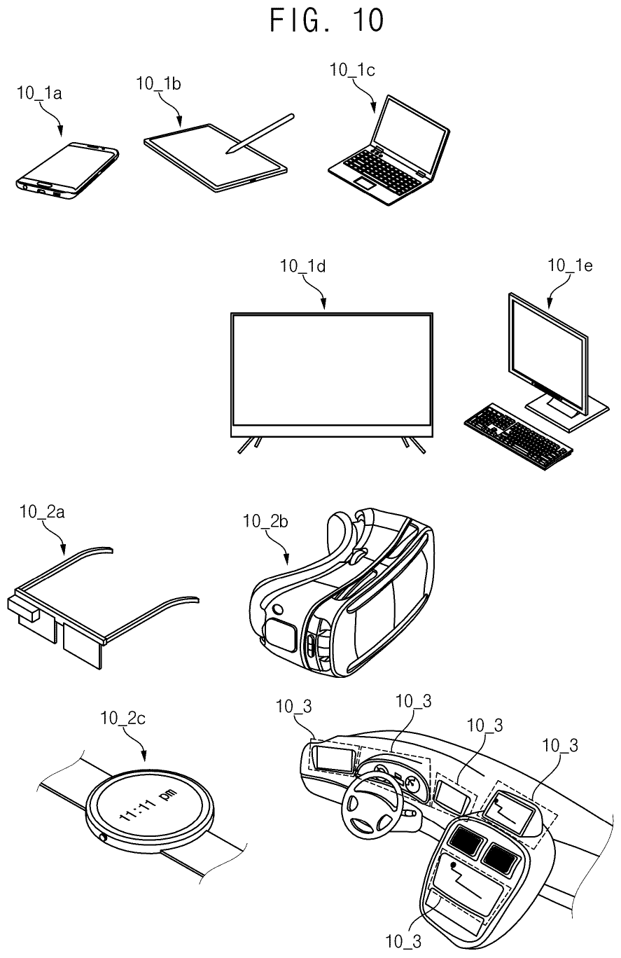

FIG. 9 is a block diagram illustrating an electronic device according to an embodiment.

Referring to FIG. 9, an electronic device 10 according to an embodiment may include a display module 11, a processor 12, a memory 13, and a power module 14.

In an embodiment, the electronic device 10 may include the display device 100 of FIG. 1. The electronic device 10 may further include modules or devices with additional functions other than the display device.

The processor 12 may include at least one of a central processing unit (CPU), an application processor (AP), a graphic processing unit (GPU), a communication processor (CP), an image signal processor (ISP), and a controller. The processor 12 may control the display device.

In an embodiment, the processor 12 may be configured to provide an image data signal and/or an input control signal to the display device.

The memory 13 may store data information desirable for the operation of the processor 12 or the display module 11. When the processor 12 executes the application stored in the memory 13, an image data signal and/or an input control signal may be transmitted to the display module 11, and the display module 11 may process the received signal and output image information on a display screen.

The power module 14 may include a power supply module, such as a power adapter or a battery device, and a power conversion module which converts the power supplied by the power supply module to generate power required for the operation of the electronic device 10.

In an embodiment, the electronic device 10 may further include a sensor module including the infrared sensor or the like.

At least one of each component of the electronic device 10 described above may be included in the display device according to embodiments. Some of the individual modules functionally included in a module may be included in the display device, and other portions may be provided separately from the display device. For example, the display device may include the display module 11, and the processor 12, the memory 13, and the power module 14 may be provided in the form of other devices in the electronic device 10 other than the display device.

FIG. 10 is an example diagram illustrating an electronic device according to various embodiments.

Referring to FIGS. 9 and 10, various electronic devices 10 to which the display device according to embodiments are applied may include not only image display electronic devices such as a smartphone 10_1a, a tablet 10_1b, a laptop 10_1c, a TV 10_1d, and a computer monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (CID) disposed on a dashboard, and a room mirror display, or the like.

Therefore, embodiments of the disclosure provide a display device and an electronic device including the same that reduces a moiré interference pattern and limits a viewing angle without substantially reducing the ability of an infrared sensor to sense external objects. This is achieved by including light blocking lines on a front side of a display panel and throughout the display area that may include (or be composed of) lactam black (a lactam based material having a black appearance). The lines may extend in an extension direction and may be spaced apart from each other at regular intervals, and may form an inclination angle with a horizontal direction of the display device. Such lactam black light blocking lines are transparent to infrared radiation while limiting visible light transmission so that an infrared sensor in the display device can still adequately sense external objects.

Although embodiments and implementations have been described herein, other embodiments and modifications will be apparent from this description. Accordingly, the disclosure is not necessarily limited to such embodiments, but rather to the broader scope of the appended claims and various obvious modifications and equivalent arrangements as would be apparent to a person of ordinary skill in the art.

What is claimed is:

1. A display device comprising:
a display panel including a first display area having a first resolution and a second display area having a second resolution less than the first resolution; and
a light control layer disposed on the display panel that controls a path of light emitted from the display panel, and including:
a plurality of light blocking lines each extending in an extension direction, the plurality of light blocking lines are spaced apart from each other at a constant interval in a direction perpendicular to the extension direction in both the first display area and the second display area, the plurality of light blocking lines including lactam black; and
a light transmitting layer overlapping the plurality of light blocking lines.

2. The display device of claim 1, wherein the plurality of light blocking lines have an infrared radiation transmittance of at least about 76%.

3. The display device of claim 1, wherein the plurality of light blocking lines have an optical density of at least about 2 with respect to a CIE standard illuminant A at a thickness of 3 micrometers.

4. The display device of claim 1, wherein the plurality of light blocking lines have an optical density of at least about 2 or more with respect to a CIE standard illuminant C at a thickness of 3 micrometers.

5. The display device of claim 1, wherein the light control layer has an infrared radiation transmittance of at least about 90%.

6. The display device of claim 1, wherein the second display area has an infrared radiation transmittance in a range of about 25% to about 40%.

7. The display device of claim 1, wherein a pitch of the plurality of light blocking lines in the first display area is substantially equal to a pitch of the plurality of light blocking lines in the second display area.

8. The display device of claim 1, wherein a pitch of the plurality of light blocking lines is in a range of about 40 micrometers to about 50 micrometers.

9. The display device of claim 1, wherein a width of each of the plurality of light blocking lines in the first display area is substantially equal to a width of each of the plurality of light blocking lines in the second display area.

10. The display device of claim 1, wherein a width of each of the plurality of light blocking lines is in a range of about 13 micrometers to about 16 micrometers.

11. The display device of claim 1, wherein
the first display area includes first pixel areas that are repeatedly disposed in a first direction and a second direction perpendicular to the first direction,
the second display area includes second pixel areas that are repeatedly disposed in the first direction and the second direction, and
a size of each of the second pixel areas is greater than a size of each of the first pixel areas.

12. The display device of claim 11, wherein each of the plurality of light blocking lines extends at an inclination angle with respect to a virtual straight line extending in the first direction.

13. The display device of claim 12, wherein the inclination angle is in a range of about 5 degrees to about 10 degrees.

14. The display device of claim 1, further comprising:
an anti-reflection layer disposed between the display panel and the light control layer.

15. An electronic device comprising:
a display device including:
a display panel including a first display area having a first resolution and a second display area having a second resolution less than the first resolution; and
a light control layer disposed on the display panel that controls a path of light emitted from the display panel; and
a processor configured to transmit an image data signal and an input control signal to the display device,
wherein the light control layer includes:
a plurality of light blocking lines each extending in an extension direction, the plurality of light blocking lines are spaced apart from each other at a constant interval in a direction perpendicular to the extension direction in both the first display area and the second display area, the plurality of light blocking lines including lactam black; and
a light transmitting layer overlapping the plurality of light blocking lines.

16. The electronic device of claim 15, wherein the plurality of light blocking lines have an infrared radiation transmittance of at least about 76%.

17. The electronic device of claim 15, wherein the plurality of light blocking lines have an optical density of at least about 2 with respect to a CIE standard illuminant A at a thickness of 3 micrometers.

18. The electronic device of claim 15, wherein the plurality of light blocking lines have an optical density of at least about 2 with respect to a CIE standard illuminant C at a thickness of 3 micrometers.

19. The electronic device of claim 15, wherein the light control layer has an infrared radiation transmittance of at least about 90%.

20. The electronic device of claim 15, wherein the second display area has an infrared radiation transmittance in a range of about 25% to about 40%.
